(19) United States
(12) Patent Application Publication
(10) Pub. No.: US 2009/0180250 A1
(43) Pub. Date: Jul. 16, 2009

(54) PEAK-LOAD COOLING OF ELECTRONIC COMPONENTS BY PHASE-CHANGE MATERIALS

(75) Inventors: Marc Holling, Hamburg (DE); Wilson Willy Casas Noriega, Hamburg (DE)

Correspondence Address: BARNES & THORNBURG LLP, 11 SOUTH MERIDIAN, INDIANAPOLIS, IN, 46204, US

(73) Assignee: AIRBUS DEUTSCHLAND GMBH, Hamburg (DE)

(21) Appl. No.: 12/352,286

(22) Filed: Jan. 12, 2009

Related U.S. Application Data
(60) Provisional application No. 61/020,434, filed on Jan. 11, 2008.

(30) Foreign Application Priority Data
Jan. 11, 2008 (DE) 102008004053.3

(51) Int. Cl. H05K 7/20

(52) U.S. Cl. 361/690; 361/700

(57) ABSTRACT

Cooling device for electronic components, in particular for power electronics in an aircraft, comprising an energy storage device which is in heat-conducting communication with at least one electronic component which is to be cooled, and which storage device is in the form of a material which performs a change in phase on absorbing the waste heat from the at least one electronic component.

The invention relates to the, preferably brief, cooling of electronic components, particularly of power electronics in an aircraft, with the aid of phase-change materials on board aircraft. In this cooling arrangement, the electronic components are brought into direct or indirect thermal contact with a material which passes through a change in phase at certain temperatures which are to be adapted to the application.

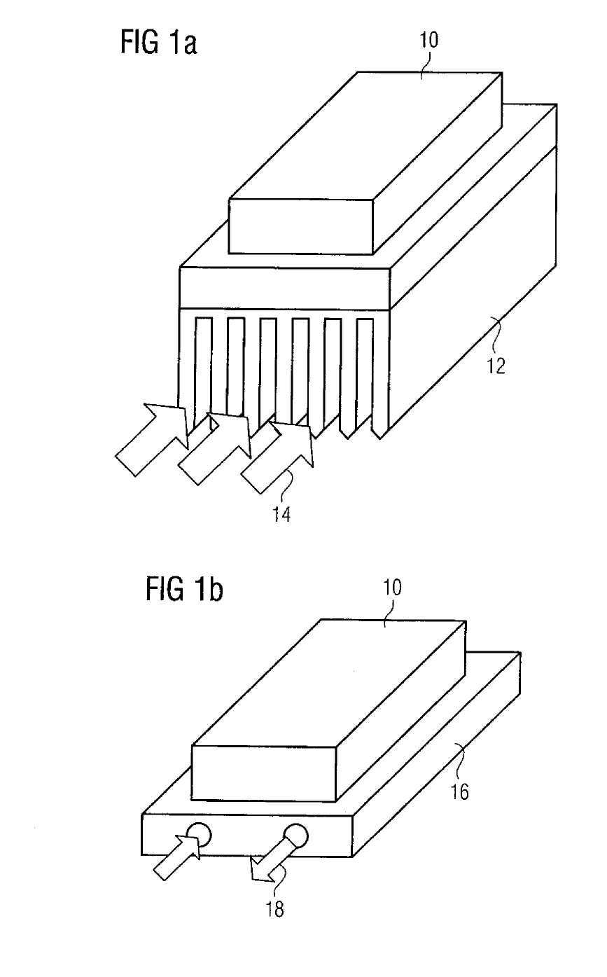

These days, electronic components in aircraft are cooled either with air or with the aid of liquid cooling by means of so-called cold plates, such as are represented, for example, in FIGS. 1a and 1b, in order to limit or prevent the heating-up of the components that results from power dissipation when the electronic components are in operation. In the air cooling arrangement shown in FIG. 1a, an electronic component 10 is connected to a cooling body 12 in order to enlarge the heat transfer surface. This cooling body 12 has cold air 14, which absorbs and conducts away heat, flowing through it. In order to be able to ensure an adequate cooling action under all ambient conditions, it is necessary under certain circumstances, for this type of cooling, to pre-cool the air actively with a refrigerating machine before it can be used for cooling the electronic components 10.

In the liquid cooling arrangement shown in FIG. 1b, an electronic component 10 is brought into contact with a cooling plate 16 through which a liquid 18 flows. Because of the higher heat capacity of liquids compared to air (or gases), cooling can take place with a lower volume flow and/or higher entry temperature in order to achieve the required cooling power.

What is common to both methods of cooling, liquid cooling and air cooling, is that they are designed for the maximum possible heat flow in order to guarantee reliable operation of the components to be cooled. The consequence of this is that, for electronic components, and particularly for power electronics, which are in operation only briefly or in which temporary peak loads occur, it is necessary to install a relatively large and therefore also heavy cooling system, a fact which is disadvantageous, particularly for aeronautical operations. Moreover, the design of these cooling systems is susceptible to faults because of the use of fans or pumps and valves.

The object of the present invention is accordingly to provide a cooling device which is capable, by means of a simple design, of absorbing a high heat flow, at least briefly, without entailing a major disadvantage in terms of weight.

This object is achieved by means of the subject-matter of the independent claim. Preferred embodiments emerge from the dependent claims.

The cooling device for cooling electronic components, particularly aircraft electronics, comprises an energy storage device which is in heat-conducting communication with at least one electronic component and is preferably designed as a closed-off chamber system. The energy storage device may be in direct or indirect communication with the electronic component for the purpose of cooling said component, or may be in direct or indirect communication with a number of electronic components for the purpose of cooling said components. The energy storage device comprises at least one phase-change material, preferably a chemical wax with a melting point in the range between 70 and 80 degrees, which may be in indirect or direct contact with the electronic component or components. When the at least one electronic component is in operation, heat, for example in the form of power dissipation from the component, is produced which can lead to impairment of operation and damage to the electronic component, so that this heat must be absorbed and conducted away. The phase-change material is designed to perform a change in phase as a result of absorbing the waste heat from the electronic component, without itself heating up appreciably in the process. In other words, the material is designed to absorb the waste heat from the electronic component and to pass, at least virtually constant temperature, through a change in phase, such as a change in the aggregate state for example, so that the energy absorbed brings about, initially, only a change in phase and not heating-up of the material.

The heat-absorbing capacity of the material at least virtually constant temperature is based on the fact that the material is capable of passing through a change in phase when it absorbs energy and is thus able to store, in a latent manner, the waste heat given off by the electronic component. In the case of a change in the aggregate state from solid to liquid, for example, the energy absorbed by the material may serve to break up the solid-state lattice without the temperature of the material itself increasing appreciably.

Depending upon the material which is chosen, and the mass of material which is chosen, different amounts of energy can be absorbed before the change in phase has come to an end and the temperature of the material rises. It is thus possible, according to the electronic component or components to be cooled, to choose a different material and/or a different mass of material which is/are suitable for absorbing, for example, the maximum waste-heat flow or the maximum waste heat from the electronic components. In particular, it is possible to match the phase-change material to the component or components to be cooled in such a way that said material performs a change in phase when the temperature of the waste-heat flow from the component which is given off, for example per unit of time, exceeds a predetermined threshold value. If, on the other hand, the temperature of the waste-heat flow is not high enough, that is to say the temperature of said waste-heat flow fails to reach the threshold value, the phase-change material will preferably not perform any change in phase, and will therefore not absorb and store any waste heat from the component. The phase-change material can thus be matched precisely to the particular component, e.g. to that duration of operation of the component which is to be anticipated, or to the nature of the component. For components in which even slight heating-up can lead to damage of the component or to impairment of its operation, use may be made of phase-change materials which perform a change in phase even at fairly low temperatures. For components which are used in continuous operation, it is possible to use, e.g., materials having a high energy-absorbing capacity.

The energy storage device is preferably designed as a closed-off chamber system. The energy input absorbed cannot then, as a rule, be conducted away while the electronic component and the cooling device are in operation. The material and the cooling device are therefore preferably designed in such a way that the material can be brought back into the initial state after the absorption of the waste-heat flow, for example after the absorption of the maximum possible waste heat up to the end of the change in phase, by giving off the energy absorbed. The phase-change material may, for example, be regenerated again by giving off energy to the environment or to a cooling medium.

The energy storage device comprises one or more phase-change materials which are matched, for example with respect to the nature or mass of the material, to specific electronic components or groups of components, it being possible, for example, for groups of the electronic components to be in direct or indirect contact with an appertaining phase-change material or materials which is/are matched to them, or else for each of the components to be in direct or indirect contact with its appertaining phase-change material which is matched to it.

The energy storage device may also be in communication with a secondary cooling system, for example an air or liquid cooling system. When, for example, the electronic components are operating normally or an average power dissipation is given off, the secondary cooling system may be used for the permanent cooling of the electronic components, and the energy storage device may be used, for example at determined points in time or intervals in time, in addition to the cooling system or instead of it, in order to absorb and cushion any waste-heat peaks that may occur. Consequently the weight of the cooling system, which serves, for example, as the main cooling system for the electronic components, and therefore also the weight of the cooling device, can be reduced, compared to conventional cooling systems such as, e.g. those shown in FIGS. 1a and 1b, since it is not necessary to design it for maximum possible power dissipations and waste-heat flows, in particular for power-dissipation peaks and waste-heat peaks. If the temperature of the waste-heat flow fails to reach, e.g., a predetermined threshold value, above which the energy storage device performs a change in phase, the waste heat is not absorbed by the energy storage device but is able to flow through the latter, for example, without leading to a change in phase, and is conducted away by the secondary cooling system. If the temperature of the waste heat rises to, or above, the threshold value, the phase-change material passes through a change in phase and stores the waste heat in a latent manner as energy. It is thereby possible to provide an easily realisable combination consisting of the energy storage device and the secondary cooling system. By means of an arrangement of this kind, power-dissipation peaks can be absorbed by the energy storage device and the normal cooling system does not need to be designed for the maximum power dissipation by increasing the size and mass. This leads to a reduction in the size and mass of the cooling device, compared with conventional cooling systems.

Alternatively, it is possible to use the energy storage device for cooling electronic components which are only in operation briefly and thus generate, e.g., high power dissipations only over brief time intervals, without the secondary cooling system, a fact which likewise leads to a diminished weight of the cooling device, compared with conventional cooling systems.

According to one variant of embodiment, a combination of the energy storage device and the secondary cooling system can be designed in such a way that, when the component is operating normally, the energy storage device absorbs the waste heat and the secondary cooling system, or a number of secondary cooling systems, function(s) as an emergency cooling system. For example, it is possible, if the cooling device contains, for example, the energy storage device and a cooling system which is connected to the latter, for example an air or liquid cooling system, for the cooling device to comprise an activating unit which is configured in such a way that it activates the cooling system and/or the energy storage device for cooling the electronic components, in dependence upon the level of the waste heat from said electronic components. It is preferably possible, when the cooling device is in a basic state, e.g. under normal operating conditions, to use only the energy storage device for cooling the electronic components. If the absorption capacity of the energy storage device is exhausted, through the fact that it has absorbed the maximum quantity of energy it is capable of absorbing, the activating unit is able to detect a heating-up of the phase-change material that occurs in the event of a continuing infeed of heat, and to thereupon bring the secondary cooling system, either in addition to or instead of the energy storage device, into heat-conducting communication with the electronic component as an emergency cooling system for the purpose of conducting away the waste heat.

The invention will be described more precisely below with the aid of preferred embodiments.

FIG. 1a shows a diagrammatic layout of a conventional air cooling system for cooling an electronic component;

FIG. 1b shows a diagrammatic layout of a conventional liquid cooling system for cooling an electronic component;

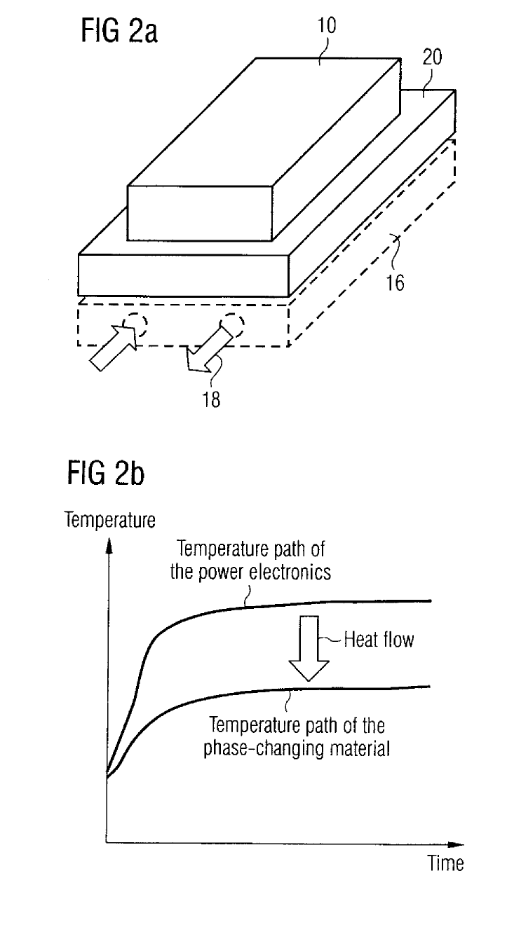

FIG. 2a shows a diagrammatic layout of cooling devices according to a first and second embodiment of the present invention; and

FIG. 2b shows a qualitative temperature path over time for the phase-change material according to the first embodiment from FIG. 2a and for the electronic component.

FIG. 1a shows a conventional air cooling system for an electronic component 10 having an air-cooling body 12 for cooling said component. If the electronic component 10 is cooled with air, said component is connected to the air-cooling body 12. Flowing through said air-cooling body 12 is a cold, preferably pre-cooled, flow of air 14 which absorbs heat and thus conducts away the heat which is produced when the electronic component 10 is operating.

FIG. 1b shows a conventional cooling system for an electronic component 10, with a liquid-cooling plate 16 for cooling said component. In the case of the liquid cooling arrangement according to FIG. 1b, the electronic component 10 is brought into contact with the liquid-cooling plate 16, through which a flow of cooling liquid 18 flows. Said flow of cooling liquid 18 is capable of absorbing and conducting away the heat which is given off by the electronic component 10 when operating.

FIG. 2a shows a cooling device according to a first embodiment of the present invention, with a closed-off energy-storing chamber 20 for cooling an electronic component 10. FIG. 2a also shows, as a result of the addition of the liquid-cooling plate 16, which is represented in broken lines, to the cooling device according to the first embodiment, a cooling device according to a second embodiment of the present invention for cooling an electronic component 10, which cooling device has a closed-off energy-storing chamber 20 and a liquid-cooling plate 16.

According to the first embodiment, the electronic component 10 is directly in contact with the energy-storing chamber 20 which contains a phase-change material. If the electronic component 10 heats up because of the power dissipation occurring as a result of the operation of said component, the energy-storing chamber 20 is able to absorb the waste heat from the component, so that the phase-change material performs a change of phase into another phase, for example into another aggregate state, as a result of the energy absorbed. The absorption of the waste heat by the phase-change material does not lead, initially, to any increase in the temperature of the material, since the change in phase runs its course at least virtually constant temperature. If the change in phase has come to an end after the absorption of a certain energy input, a further infeed of energy leads to heating-up of the material and thereby to an increase in temperature. The phase-change material according to the first embodiment is matched to the electronic component 10, that is to say said material is directed, in terms of its nature and mass, towards the absorption of the maximum power dissipation which is to be anticipated, or towards the maximum energy dissipation of the electronic component 10 which is to be anticipated during the period of operation.

According to the second embodiment, the cooling device has, in addition to the energy-storing chamber 20 with the phase-change material, a liquid-cooling plate 16 through which a flow of liquid 18 is able to flow for the purpose of cooling the electronic component 10. The liquid-cooling plate 16 may, as shown in FIG. 2a, be arranged on the same side of the component 10 as the energy-storing chamber 20, in indirect contact with said component, or may be arranged on the other side of the latter, with respect to the energy-storing chamber 20, in direct contact with said component 10 (not shown). According to the second embodiment, under normal operating conditions, particularly when the normal, average waste heat is given off by the electronic component 10, only the liquid-cooling plate 16 is used for cooling said component, through the fact that the liquid 18 flowing through said liquid-cooling plate 16 absorbs and transports away the heat given off by the electronic component 10. The liquid-cooling plate 16 is designed, with respect to its capacity for conducting away heat, for normal operation of the electronic component 10. This means that, when said component 10 is operating normally, waste heat is generated, the temperature of which is not sufficient to cause a change in phase of the phase-change material, since the temperature of the waste-heat flow fails to reach a threshold value above which the material performs a change in phase. As a result, the waste heat flows through the energy-storing chamber 20 without being absorbed by the latter and can be conducted away by the liquid plate in the known manner. If, however, waste heat which is brought about by power dissipation from the electronic component 10 and the temperature of which lies above the threshold value is generated, the energy-storing chamber 20 with the phase-change material will, instead of the liquid-cooling plate 16, absorb the waste heat produced by the power-dissipation peak. When the threshold value is not reached, the energy-storing chamber 20 will no longer absorb the waste heat, and the cooling device runs, once again, under the normal operating conditions in which the liquid-cooling plate 16 serves to cool the electronic component 10.

FIG. 2b illustrates a qualitative temperature path over time for the phase-change material according to the first embodiment shown in FIG. 2a and for the electronic component (power electronics). It becomes clear that, when there is a major increase in temperature in the electronic component, the temperature of the phase-change material increases substantially less strongly and the heat flow emanating from the electronic component can be absorbed by said phase-change material in order to carry out a change in phase.

1. Cooling device for electronic components, in particular for power electronics in an aircraft, comprising an energy storage device which is in heat-conducting communication with at least one electronic component (10) which is to be cooled, and which energy storage device is in the form of a material which performs a change in phase on absorbing waste heat from the at least one electronic component (10), wherein the energy storage device is in heat-conducting communication with a secondary cooling system (16), and wherein the phase-change material is adapted to absorb the waste heat from the electronic component (10) when the temperature of the waste-heat flow from said electronic component (10) exceeds a threshold value, and wherein the secondary system (16) is adapted to absorb the waste heat from the electronic component (10) when the temperature of the waste-heat flow from said electronic component (10) does not exceed the threshold value.

2. Cooling device according to claim 1, wherein the phase-change material performs a change in phase for the purpose of absorbing the waste heat from the electronic component (10), when the temperature of the waste-heat flow from the electronic component (10) exceeds a predetermined threshold value.

3. Cooling device according to claim 1, wherein the energy storage device is designed as a closed-off energy-storing chamber (20).

4. Cooling device according to claim 1, wherein the electronic component (10) is in indirect or direct contact with the phase-change material.

5. Cooling device according to claim 1, wherein the change in phase performed by the phase-change material is reversible.

6. Cooling device according to claim 1, wherein the secondary cooling system (16) is designed as an air cooling system or liquid cooling system.

7. Cooling device according to claim 1, further comprising an activating unit which is capable of activating the secondary cooling system and/or the energy storage device in dependence upon the quantity of the waste heat generated by the electronic component (10) and/or upon the temperature of the waste-heat flow generated by said electronic component (10).

8. Cooling device according to claim 7, wherein the activating unit is configured for the purpose of activating the energy storage device when the waste heat or the temperature of the waste-heat flow exceeds a predetermined threshold value.

9. Cooling device according to claim 1, wherein the phase-change material comprises a number of materials which perform a change in phase at a different temperature in each case.

10. Cooling device according to claim 2, wherein the energy storage device is designed as a closed-off energy-storing chamber (20).

11. Cooling device according to claim 2, wherein the electronic component (10) is in indirect or direct contact with the phase-change material.

12. Cooling device according to claim 3, wherein the electronic component (10) is in indirect or direct contact with the phase-change material.

13. Cooling device according to claim 2, wherein the change in phase performed by the phase-change material is reversible.

14. Cooling device according to claim 3, wherein the change in phase performed by the phase-change material is reversible.

15. Cooling device according to claim 4, wherein the change in phase performed by the phase-change material is reversible.

16. Cooling device according to claim 6, further comprising an activating unit which is capable of activating the secondary cooling system and/or the energy storage device in dependence upon the quantity of the waste heat generated by the electronic component (10) and/or upon the temperature of the waste-heat flow generated by said electronic component (10).

17. Cooling device according to claim 2, wherein the phase-change material comprises a number of materials which perform a change in phase at a different temperature in each case.

18. Cooling device according to claim 4, wherein the phase-change material comprises a number of materials which perform a change in phase at a different temperature in each case.

19. Cooling device according to claim 5, wherein the phase-change material comprises a number of materials which perform a change in phase at a different temperature in each case.

20. Cooling device according to claim 6, wherein the phase-change material comprises a number of materials which perform a change in phase at a different temperature in each case.
